(19) United States
(12) Patent Application Publication
(10) Pub. No.: US 2019/0228980 A1
(43) Pub. Date: Jul. 25, 2019

(54) WAFER PRODUCING METHOD AND WAFER PRODUCING APPARATUS

(71) Applicant: DISCO CORPORATION, Tokyo (JP)

(72) Inventors: Ryohei YAMAMOTO, Tokyo (JP); Kazuya HIRATA, Tokyo (JP)

(21) Appl. No.: 16/251,876

(22) Filed: Jan. 18, 2019

(30) Foreign Application Priority Data
Jan. 22, 2018 (JP) 2018-007972

(51) Int. Cl. H01L 21/304; H01L 21/78; H01L 21/322; B23K 26/00; B23K 26/53; B28D 5/00

(52) U.S. Cl. CPC H01L 21/304; H01L 21/78; B28D 5/0011; B23K 26/0006; B23K 26/53; H01L 21/322

(57) ABSTRACT

A wafer producing method of producing a wafer from a hexagonal single crystal ingot, the method including positioning a focal point of a laser beam of such a wavelength as to be transmitted through the hexagonal single crystal ingot at a depth corresponding to a thickness of a wafer to be produced from an end face of the hexagonal single crystal ingot and applying the laser beam to the hexagonal single crystal ingot to form a separation layer, positioning an ultrasonic wave generating unit so as to face the wafer to be produced with a layer of water interposed therebetween and generating an ultrasonic wave through the layer of water to break down the separation layer, and detecting separation of the wafer to be produced from the hexagonal single crystal ingot according to change in sound.

### BACKGROUND OF THE INVENTION

### Field of the Invention

The present invention relates to a wafer producing method of producing a wafer from a hexagonal single crystal ingot and to a wafer producing apparatus.

### Description of the Related Art

Devices such as integrated circuits (ICs), large scale integrations (LSIs), and light emitting diodes (LEDs) are formed by stacking a functional layer on a front surface of a wafer formed from silicon (Si), sapphire (Al₂O₃), or the like as a base material and demarcating the functional layer by a plurality of crossing division lines. In addition, devices such as power devices and LEDs are formed by stacking a functional layer on a front surface of a wafer containing hexagonal single crystal silicon carbide (SiC) as a base material and demarcating the functional layer by a plurality of crossing division lines. The wafer formed with the devices is laser-processed along the division lines by a laser processing apparatus to be divided into individual device chips, and the individual device chips thus obtained are used in electric equipment such as mobile phones and personal computers.

The wafer formed with the devices is generally produced by slicing a semiconductor ingot with a circular column shape by a wire saw. A front surface and a back surface of the sliced wafer are mirror-finished by polishing (see Japanese Patent Laid-Open No. 2000-94221, for example). However, when the ingot is sliced by the wire saw and the front surface and the back surface of the sliced wafer are polished, most part (70% to 80%) of the ingot is discarded, which is uneconomical. Particularly, a hexagonal single crystal SiC ingot is high in hardness and is difficult to slice by a wire saw, requiring a considerable time for slicing. Accordingly, poor productivity and high unit cost of the ingot are caused, which poses a problem in efficiency of producing a wafer.

To address this problem, the applicant of the present application has proposed a technique in which a laser beam of such a wavelength as to be transmitted through hexagonal single crystal SiC is applied to a hexagonal single crystal SiC ingot, with a focal point of the laser beam positioned inside the hexagonal single crystal SiC ingot, to form a separation layer at a cutting plane, and a wafer is separated from the hexagonal single crystal SiC ingot with the separation layer as a starting point for separation (see Japanese Patent Laid-Open No. 2016-111143, for example).

### SUMMARY OF THE INVENTION

However, there is a problem in that it is difficult to separate the wafer from the hexagonal single crystal SiC ingot with the separation layer as the starting point for separation and the production efficiency is low. In addition, there is also another problem in that it is difficult to determine whether or not separation of the wafer from the hexagonal single crystal SiC ingot has completed.

It is therefore an object of the present invention to provide a wafer producing method and a wafer producing apparatus capable of easily separating a wafer from a hexagonal single crystal ingot with a separation layer as a starting point for separation, and easily determining whether or not the separation of the wafer from the hexagonal single crystal SiC ingot has completed.

In accordance with an aspect of the present invention, there is provided a wafer producing method of producing a wafer from a hexagonal single crystal ingot, the method including a separation layer forming step of positioning a focal point of a laser beam of such a wavelength as to be transmitted through the hexagonal single crystal ingot at a depth corresponding to a thickness of a wafer to be produced from an end face of the hexagonal single crystal ingot and applying the laser beam to the hexagonal single crystal ingot to form a separation layer, an ultrasonic wave generating step of positioning an ultrasonic wave generating unit so as to face the wafer to be produced with a layer of water interposed therebetween and generating an ultrasonic wave through the layer of water to break down the separation layer, and a separation detecting step of detecting separation of the wafer to be produced from the hexagonal single crystal ingot according to change in sound.

Preferably, in the separation detecting step, a microphone collects sound, and when a frequency of the collected sound an amplitude of which becomes a peak reaches a predetermined value, it is detected that the wafer has been separated.

Preferably, the hexagonal single crystal ingot is a hexagonal single crystal SiC ingot having a c-axis and a c-plane which is orthogonal to the c-axis, and in the separation layer forming step, a focal point of a laser beam of such a wavelength as to be transmitted through the hexagonal single crystal SiC ingot is positioned at a depth corresponding to a thickness of a wafer to be produced from an end face of the hexagonal single crystal SiC ingot, and the laser beam is applied to the hexagonal single crystal SiC ingot to form a separation layer including a modified portion in which SiC is separated into Si and C, and cracks isotropically extending along the c-plane from the modified portion.

Preferably, the hexagonal single crystal ingot is a hexagonal single crystal SiC ingot in which the c-axis is inclined with respect to a normal line to an end face thereof and an off angle is formed by the c-plane and the end face, and in the separation layer forming step, the separation layer is formed by continuously forming the modified portion in a direction orthogonal to a direction in which the off angle is formed to form the cracks isotropically extending along the c-plane from the modified portion, relatively carrying out indexing feeding of the hexagonal single crystal SiC ingot and the focal point within a range not exceeding a width of each of the cracks in the direction in which the off angle is formed, and continuously forming modified portions in the direction orthogonal to the direction in which the off angle is formed to sequentially generate the cracks isotropically extending along the c-plane from each of the modified portions.

In accordance with another aspect of the present invention, there is provided a wafer producing apparatus which produces a wafer from a hexagonal single crystal ingot in which a separation layer is formed by positioning a focal point of a laser beam of such a wavelength as to be transmitted through the hexagonal single crystal ingot at a depth corresponding to a thickness of a wafer to be produced from an end face of the hexagonal single crystal ingot and applying the laser beam to the hexagonal single crystal ingot. The wafer producing apparatus includes an ultrasonic wave generating unit having an end face which faces the wafer to be produced and generating an ultrasonic wave, a microphone disposed adjacent to the hexagonal single crystal ingot and collecting sound which is propagated in the air from the hexagonal single crystal ingot, and separation detecting means coupled with the microphone and detecting separation of the wafer to be produced from the hexagonal single crystal ingot according to change of the collected sound.

According to the wafer producing method, it is possible to easily separate a wafer from a hexagonal single crystal ingot with a separation layer as a starting point for separation, and to easily determine whether or not the separation of the wafer from the hexagonal single crystal ingot has completed.

According to the wafer producing apparatus, it is possible to easily separate a wafer from a hexagonal single crystal ingot with a separation layer as a starting point for separation, and to easily determine whether or not the separation of the wafer from the hexagonal single crystal ingot has completed.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view of a wafer producing apparatus according to an embodiment of the present invention;

FIG. 2 is a perspective view of the wafer producing apparatus illustrating a state of causing an ingot holding unit illustrated in FIG. 1 to hold an SiC ingot;

FIG. 3A is a front elevational view of the SiC ingot;

FIG. 3B is a plan view of the SiC ingot;

FIG. 4A is a perspective view illustrating a state in which a separation layer is formed in the SiC ingot illustrated in FIG. 3A;

FIG. 4B is a front elevational view illustrating a state in which the separation layer is formed in the SiC ingot illustrated in FIG. 3A;

FIG. 5A is a plan view of the SiC ingot formed with the separation layer;

FIG. 5B is a cross-sectional view taken along a line B-B in FIG. 5A;

FIG. 6 is a front elevational view of a wafer producing apparatus illustrating a state in which an ultrasonic wave is applied to the SiC ingot;

FIG. 7 is a graph indicating a relation between a frequency and an amplitude of sound collected by a microphone before the wafer is separated;

FIG. 8 is a graph indicating a relation between a frequency and an amplitude of sound collected by the microphone after the wafer is separated;

FIG. 9 is a front elevational view of the wafer producing apparatus illustrating a state in which a wafer holding unit is in intimate contact with the wafer which has been separated; and

FIG. 10 is a front elevational view of the wafer producing apparatus illustrating a state in which the wafer which has been separated is sucked and held by the wafer holding unit.

### DETAILED DESCRIPTION OF THE PREFERRED EMBODIMENT

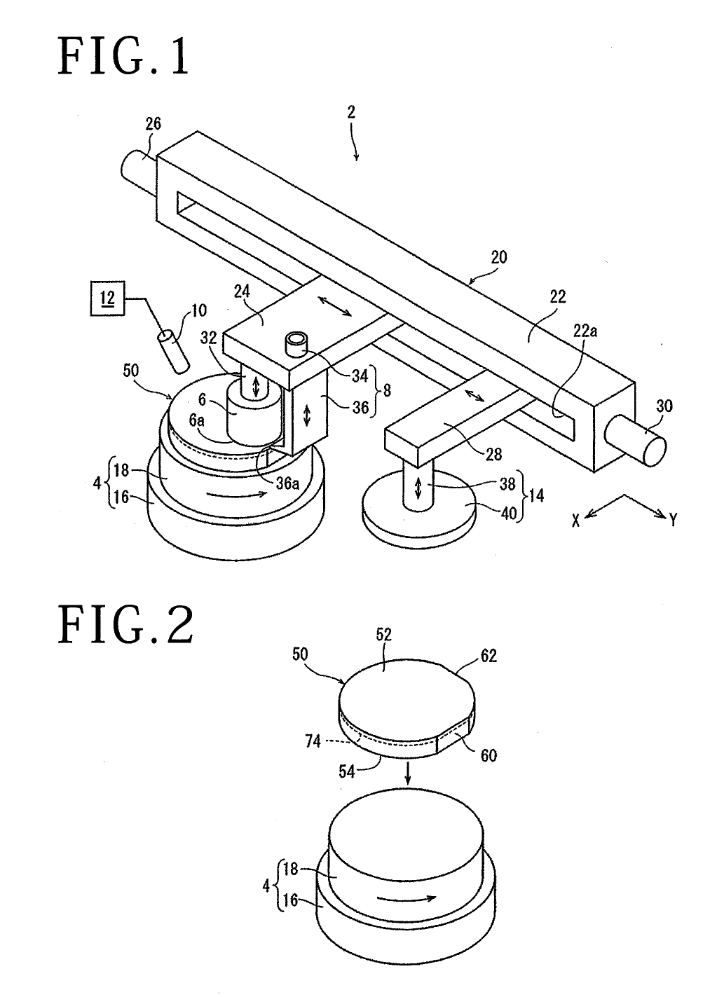

An embodiment of a wafer producing method and a wafer producing apparatus according to the present invention will be described below with reference to the drawings. First, a description regarding the wafer producing apparatus according to the present invention will be given below. A wafer producing apparatus 2 illustrated in FIG. 1 includes an ingot holding unit 4 holding a hexagonal single crystal SiC ingot (referred to simply as an ingot in an omitted manner, hereinafter), an ultrasonic wave generating unit 6 having an end face 6a which faces a wafer to be produced and generating an ultrasonic wave, water supplying means 8 supplying water between a wafer to be produced and the ultrasonic wave generating unit 6 to generate a layer of water, a microphone 10 disposed adjacent to the ingot and collecting sound which is propagated in the air from the ingot, separation detecting means 12 coupled with the microphone 10 and detecting separation of a wafer to be produced, from the ingot according to change in sound, and a wafer holding unit 14 holding the wafer which is separated from the ingot.

With reference to FIG. 1 and FIG. 2, the ingot holding unit 4 will be described below. The ingot holding unit 4 according to the present embodiment includes a base 16 with a circular column shape, a holding table 18 with a circular column shape which is rotatably mounted on an upper surface of the base 16, and a motor (not illustrated) rotating the holding table 18 about an axis passing through a center of a radial direction of the holding table 18 and extending in upward and downward directions. The ingot holding unit 4 can hold an ingot fixed to an upper surface of the holding table 18 via a suitable adhesive (an epoxy resin-based adhesive, for example). Alternatively, the ingot holding unit 4 may be configured such that a porous suction chuck (not illustrated) connected to suction means (not illustrated) is disposed on an upper end portion of the holding table 18 and a suction force is generated on an upper surface of the suction chuck by the suction means to suck and hold the ingot.

The wafer producing apparatus 2 according to the present embodiment further includes a Y-axis direction moving mechanism 20 causing the ultrasonic wave generating unit 6, the water supplying means 8, and the wafer holding unit 14 to move in a Y-axis direction indicated with an arrow Y in FIG. 1. The Y-axis direction moving mechanism 20 includes a rectangular parallelepiped frame 22 formed with a rectangular guide opening 22a extending in the Y-axis direction, a first ball screw (not illustrated) extending in the Y-axis direction inside the frame 22, a first moving piece 24 extending in an X-axis direction indicated with an arrow X in FIG. 1 from a proximal end portion coupled with the first ball screw, a first motor 26 coupled with one end of the first ball screw, a second ball screw (not illustrated) extending in the Y-axis direction inside the frame 22, a second moving piece 28 extending in the X-axis direction from a proximal end portion coupled with the second ball screw, and a second motor 30 coupled with one end of the second ball screw. The Y-axis direction moving mechanism 20 converts a rotational motion of the first motor 26 into a linear motion by the first ball screw and transmits the converted linear motion to the first moving piece 24, causing the first moving piece 24 to move along the guide opening 22a in the Y-axis direction, while at the same time, converting a rotational motion of the second motor 30 into a linear motion by the second ball screw and transmitting the converted linear motion to the second moving piece 28, causing the second moving piece 28 to move along the guide opening 22a in the Y-axis direction. Note that the X-axis direction is orthogonal to the Y-axis direction, and a plane defined by the X-axis direction and the Y-axis direction is substantially horizontal.

In the present embodiment, as illustrated in FIG. 1, at a lower surface of a distal end of the first moving piece 24, first elevating means 32 with a circular column shape which extends downward is connected, and at a lower end of the first elevating means 32, the ultrasonic wave generating unit 6 with a circular column shape is connected. With this configuration, as the first moving piece 24 moves in the Y-axis direction, the first elevating means 32 and the ultrasonic wave generating unit 6 also move in the Y-axis direction. The first elevating means 32 may include an electric cylinder having a ball screw and a motor, for example. The first elevating means 32 causes the ultrasonic wave generating unit 6 to move up and down as well as to stop at a given position, thereby causing the circular-shaped end face 6a on a lower side of the ultrasonic wave generating unit 6 to face a wafer to be produced. The ultrasonic wave generating unit 6 is formed from piezoelectric ceramics to generate an ultrasonic wave.

As illustrated in FIG. 1, the water supplying means 8 includes a cylindrical connection port 34 annexed to an upper surface of the distal end of the first moving piece 24, a nozzle 36 supported on the lower surface of the distal end of the first moving piece 24 in such a way as to freely move up and down, and a nozzle elevating mechanism (not illustrated) moving the nozzle 36 up and down. Accordingly, movement of the first moving piece 24 allows the water supplying means 8 to move in the Y-axis direction. The connection port 34 is connected to a water supplying source (not illustrated) through a suitable hose (not illustrated) for supplying water. The nozzle 36 extends downward from the lower surface of the distal end of the first moving piece 24 to be spaced from the ultrasonic wave generating unit 6 in the Y-axis direction, and then extends in the Y-axis direction toward the ultrasonic wave generating unit 6 to be slightly inclined in the downward direction. In addition, the nozzle 36 is formed into a hollow shape and communicates with the connection port 34. For example, the nozzle elevating mechanism which may include an electric cylinder causes the nozzle 36 to move up and down as well as to stop at a given position, so that an outlet port 36a of the nozzle 36 is positioned between the wafer to be produced and the end face 6a of the ultrasonic wave generating unit 6. The water supplying means 8 thus configured supplies water supplied from the water supplying source to the connection port 34 from the outlet port 36a of the nozzle 36 between the wafer to be produced and the end face 6a of the ultrasonic wave generating unit 6 to generate a layer of water.

As illustrated in FIG. 1, the microphone 10 is disposed above the holding table 18 so as to be adjacent to the ingot held on the upper surface of the holding table 18. The microphone 10 collects sound which is propagated in the air from the ingot held on the holding table 18 and converts the collected sound into an electric signal to be output. The separation detecting means 12 electrically coupled with the microphone 10 receives an electrical signal output from the microphone 10. The separation detecting means 12 is constituted by a computer and includes a central processing unit (CPU) which performs arithmetic processing according to a control program, a read only memory (ROM) in which the control program and the like is stored, and a readable/writable random access memory (RAM) in which a result of arithmetic processing or the like is stored. The separation detecting means 12 is configured such that change of an electric signal from the microphone 10 (specifically, change in sound collected by the microphone 10, and for example, change in frequency of the collected sound an amplitude of which becomes a peak) can be detected.

With reference to FIG. 1, the description will be continued. On a lower surface of a distal end of the second moving piece 28, the wafer holding unit 14 is connected, and movement of the second moving piece 28 in the Y-axis direction allows the wafer holding unit 14 to move in the Y-axis direction. The wafer holding unit 14 includes second elevating means 38 with a circular column shape which extends downward from the lower surface of the distal end of the second moving piece 28, and a circular disc-shaped holding piece 40 which is connected to a lower end of the second elevating means 38 and sucks and holds a wafer which is separated from the ingot. For example, the second elevating means 38 which may include an electric cylinder moves the holding piece 40 up and down as well as stops at a given position, causing a lower surface of the holding piece 40 to come in contact with the wafer to be produced. The holding piece 40 has a porous suction chuck (not illustrated) connected to suction means (not illustrated) annexed to a lower end thereof. Then, with the wafer separated from the ingot being in contact with the lower surface of the holding piece 40, the suction means generates a suction force on a lower surface of the suction chuck, so that the wafer separated from the ingot can be sucked and held on the holding piece 40.

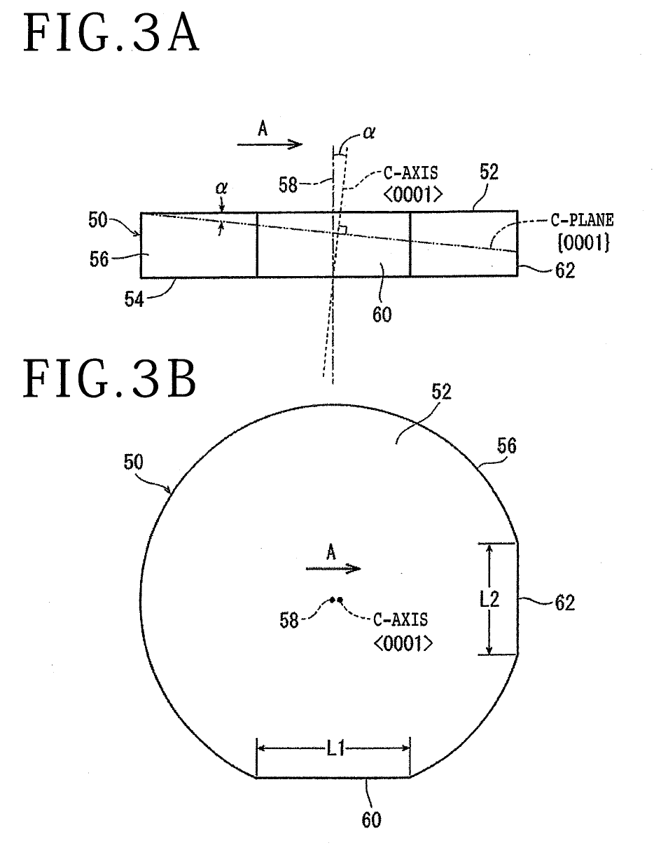

FIG. 3A and FIG. 3B illustrate an ingot 50 before the separation layer is formed. The ingot 50 is formed into a circular column shape as a whole from a hexagonal single crystal SiC and has a first end face 52 with a circular shape, a second end face 54 with a circular shape on the opposite side to the first end face 52, a circumferential face 56 located between the first end face 52 and the second end face 54, and a c-axis (<0001>direction) reaching from the first end face 52 to the second end face 54, and a c-plane ({0001} plane) orthogonal to the c-axis. In the ingot 50, the c-axis is inclined with respect to a normal line 58 to the first end face 52, and an off angle α (α=1, 3, 6 degrees, for example) is formed by the c-plane and the first end face 52. A direction in which the off angle α is formed is indicated with an arrow A in FIGS. 3A and 3B. Further, in the circumferential face 56 of the ingot 50, a first orientation flat 60 and a second orientation flat 62 each having a rectangular shape and indicating a crystal orientation are formed. The first orientation flat 60 is parallel to a direction A in which the off angle α is formed, and the second orientation flat 62 is orthogonal to the direction A in which the off angle α is formed. As illustrated in FIG. 3B, as seen from above, a length L2 of the second orientation flat 62 is shorter than a length L1 of the first orientation flat 60 (L2<L1). Note that an ingot from which a wafer may be separated by the wafer producing apparatus 2 described above after the separation layer is formed is not limited to the ingot 50 described above, and for example, a hexagonal single crystal SiC ingot may be applicable in which the c-axis is not inclined with respect to the normal line to the first end face and the off angle between the c-plane and the first end face is 0 degrees (specifically, the normal line to the first end face corresponds with the c-axis). Alternatively, a hexagonal single crystal ingot which is formed of a hexagonal single crystal gallium nitride (GaN) or the like other than a hexagonal single crystal SiC, may be applicable.

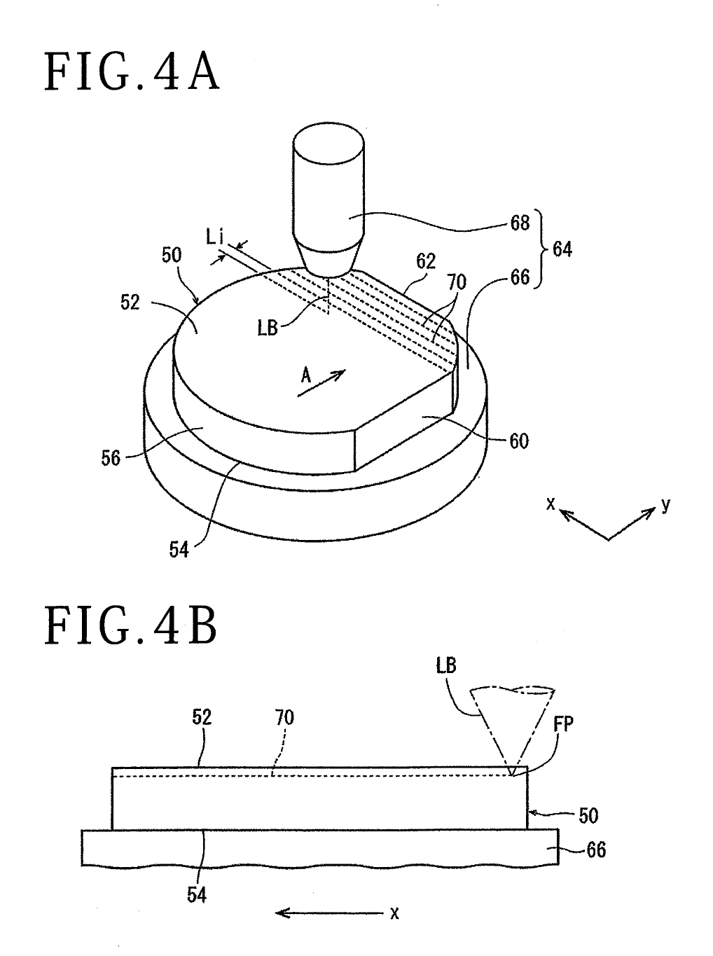

Next, a wafer producing method according to the present invention will be described. First, a separation layer forming step is performed in which a focal point of a laser beam of such a wavelength as to be transmitted through the ingot 50 is positioned at a depth corresponding to a thickness of a wafer to be produced from the end face of the ingot 50, and the laser beam is applied to the ingot 50 to form a separation layer. The separation layer forming step can be performed using, for example, a laser processing apparatus 64 which is partly illustrated in FIG. 4A. The laser processing apparatus 64 includes a chuck table 66 for holding a workpiece, and a light collector 68 emitting a pulsed laser beam LB to the workpiece held on the chuck table 66. The chuck table 66 which is configured so as to suck and hold the workpiece on an upper surface thereof is rotated about an axis extending in the upward and downward directions by rotating means (not illustrated), while the chuck table 66 advances or retracts in an x-axis direction by x-axis direction moving means (not illustrated) and advances or retracts in a y-axis direction by y-axis direction moving means (not illustrated). The light collector 68 includes a condensing lens (not illustrated) condensing a pulsed laser beam LB oscillated by a pulsed laser beam oscillator (not illustrated) of the laser processing apparatus 64 to apply the condensed pulsed laser beam LB to a workpiece. Note that the x-axis direction is a direction indicated with an arrow x in FIG. 4A and FIG. 4B and the y-axis direction is a direction indicated with an arrow y in FIG. 4A and orthogonal to the x-axis direction. A plane defined by the x-axis direction and the y-axis direction is substantially horizontal. In addition, the X-axis direction and the Y-axis direction indicated with a capital X and a capital Y in FIG. 1 may correspond to or differ from the x-axis direction and the y-axis direction indicated with a small x and a small y in FIG. 4A and FIG. 4B.

With reference to FIG. 4A and FIG. 4B, the description will be continued below. In the separation layer forming step, first, with one end face (the first end face 52 in the present embodiment) of the ingot 50 facing upward, the ingot 50 is sucked and held on an upper surface of the chuck table 66. As an alternative example, with an adhesive (an epoxy resin-based adhesive, for example) interposed between the other end face (the second end face 54 in the present embodiment) of the ingot 50 and the upper surface of the chuck table 66, the ingot 50 may be fixed to the chuck table 66. Then, an imaging unit (not illustrated) of the laser processing apparatus 64 images the ingot 50 from above. Then, on the basis of an image of the ingot 50 imaged by the imaging unit, the chuck table 66 is moved and rotated by the x-axis direction moving means, the y-axis direction moving means, and the rotating means of the laser processing apparatus 64, thereby adjusting a direction of the ingot 50 in a predetermined direction as well as a positional relation between the ingot 50 and the light collector 68 on a xy-plane. When the direction of the ingot 50 is adjusted in a predetermined direction, as illustrated in FIG. 4A, the second orientation flat 62 is aligned with the x-axis direction, whereby a direction orthogonal to the direction A in which the off angle α is formed is aligned with the x-axis direction, and the direction A in which the off angle α is formed is aligned with the y-axis direction.

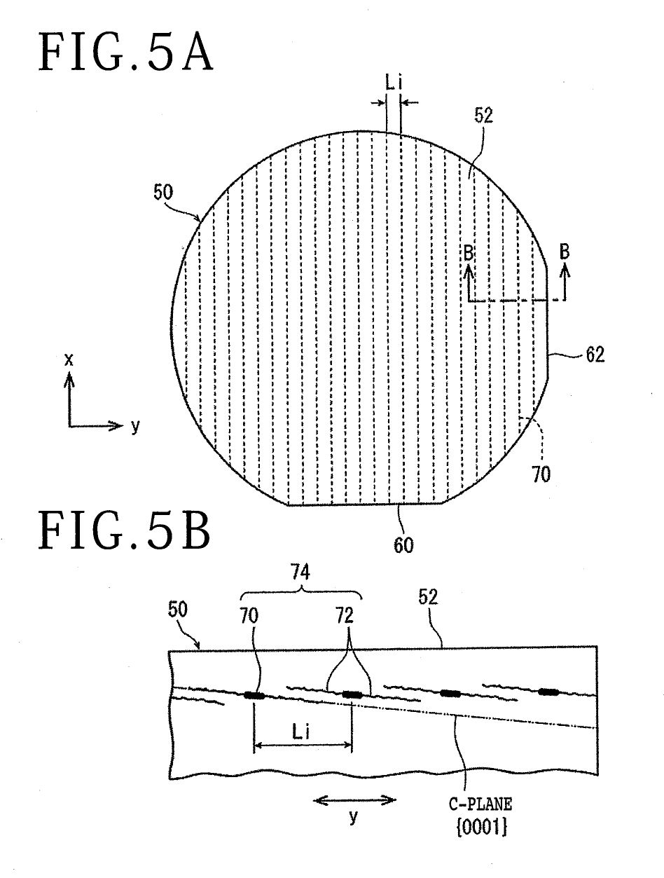

Then, focal point position adjusting means (not illustrated) of the laser processing apparatus 64 moves the light collector 68 up and down, and as illustrated in FIG. 4B, a focal point FP is positioned at a depth corresponding to a thickness of a wafer to be produced (300 μm, for example) from the first end face 52 of the ingot 50. Then, while the chuck table 66 is moved at a predetermined feed speed in the x-axis direction aligned with the direction orthogonal to the direction A in which the off angle α is formed, the separation layer forming processing is carried out in which the pulsed laser beam LB of such a wavelength as to be transmitted through the single crystal SiC is irradiated to the ingot 50 from the light collector 68. When the separation layer forming processing is carried out, as illustrated in FIG. 5A and FIG. 5B, SiC is separated into silicon (Si) and carbon (C) due to the irradiation with the pulsed laser beam LB, and the pulsed laser beam LB to be next irradiated to the ingot 50 is absorbed by C which has been formed in the previous irradiation, so that a modified portion 70 in which SiC is separated into Si and C in a chain reaction is continuously formed in the direction orthogonal to the direction A in which the off angle α is formed, while at the same time, cracks 72 isotropically extending along the c-plane from the modified portion 70 are generated. Note that, when the separation layer forming processing is carried out, the light collector 68 may be moved at a predetermined feed speed in the x-axis direction in place of the chuck table 66.

With reference to FIG. 4A to FIG. 5B, the description will be continued below. Subsequently to the separation layer forming processing, the chuck table 66 is moved by the y-axis direction moving means to indexing feed the ingot 50 and the focal point FP relatively in the y-axis direction aligned with the direction A in which the off angle α is formed by a predetermined indexing amount Li (250 to 400 μm, for example) within a range not exceeding a width of each of the cracks 72. Note that, in indexing feeding, the light collector 68 may be moved in the y-axis direction under the above-described condition in place of the chuck table 66. Further, by alternately repeating the separation layer forming processing and the indexing feeding, a plurality of modified portions 70 continuously extending in the direction orthogonal to the direction A in which the off angle α is formed are formed at intervals of the predetermined indexing amount Li in the direction A in which the off angle α is formed. In addition, the cracks 72 isotropically extending along the c-plane from each of the modified portions 70 are sequentially generated to cause the cracks 72 adjacent to each other in the direction A in which the off angle α is formed to overlap with each other as viewed in the upward and downward directions. Thus, at a depth corresponding to a thickness of a wafer to be produced from the first end face 52 of the ingot 50, a separation layer 74 which is constituted by the plurality of modified portions 70 and the cracks 72 and at which a strength for separating the wafer from the ingot 50 is lowered can be formed. Note that the separation layer forming step can be performed under the following processing condition, for example.
Wavelength of pulsed laser beam: 1064 nm
Repetition frequency: 60 kHz
Average output power : 1.5 W
Pulse width: 4 ns
Diameter of focal point: 3 μm
Numerical aperture (NA) of condensing lens: 0.65
Feeding speed: 200 mm/s

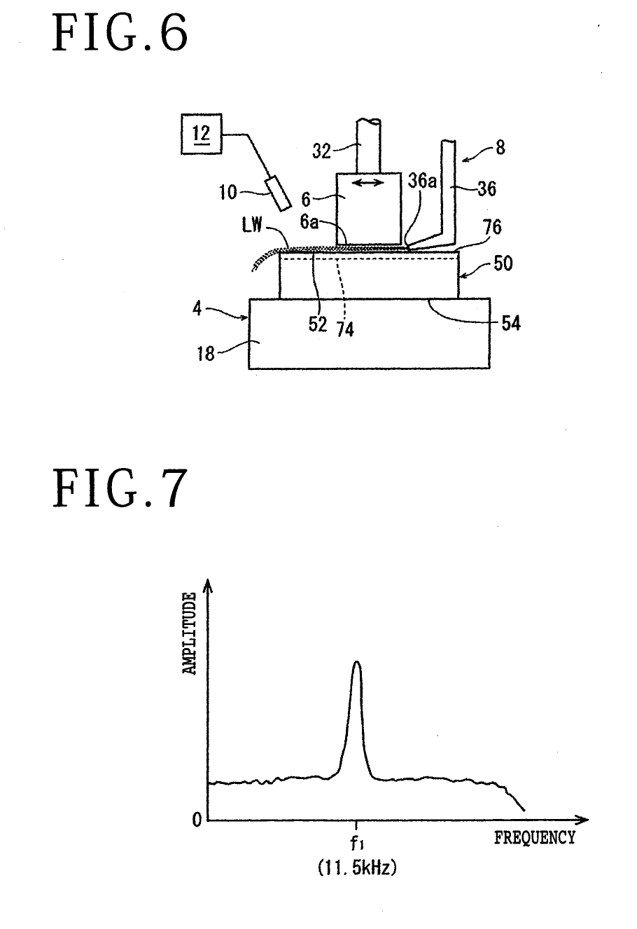

After the separation layer forming step is performed, an ultrasonic wave generating step is performed in which the ultrasonic wave generating unit 6 is positioned so as to face the wafer to be produced with the layer of water interposed therebetween, generating an ultrasonic wave through the layer of water to thereby break down the separation layer 74. In the ultrasonic wave generating step of the present embodiment, as illustrated in FIG. 2, first, with the first end face 52 which is an end face close to the separation layer 74 facing upward, the ingot holding unit 4 holds the ingot 50 on the upper surface of the holding table 18. In this case, the ingot 50 may be fixed to the holding table 18 by interposing an adhesive (an epoxy resin-based adhesive, for example) between the second end face 54 of the ingot 50 and the upper surface of the holding table 18. Alternatively, the ingot 50 may be sucked and held on the upper surface of the holding table 18 by a suction force generated thereon. Subsequently, the first motor 26 of the Y-axis direction moving mechanism 20 moves the first moving piece 24, as illustrated in FIG. 1, thereby causing the end face 6a of the ultrasonic wave generating unit 6 to face a wafer to be produced (a portion from the first end face 52 to the separation layer 74 in the present embodiment). Then, the first elevating means 32 lowers the ultrasonic wave generating unit 6 until a distance between the fist end face 52 and the end face 6a of the ultrasonic wave generating unit 6 reaches a predetermined value (substantially 2 to 3 mm, for example), after which operation of the first elevating means 32 is stopped. Further, the nozzle elevating mechanism moves the nozzle 36, so that the outlet port 36a of the nozzle 36 is positioned between the first end face 52 and the end face 6a. Then, the holding table 18 is rotated by the motor, while at the same time, as illustrated in FIG. 6, the first motor 26 moves the first moving piece 24 in the Y-axis direction, supplying water between the first end face 52 and the end face 6a from the outlet port 36a of the nozzle 36. As a result, a layer of water LW is produced therebetween, and an ultrasonic wave is generated by the ultrasonic wave generating unit 6. At this time, in such a way that the ultrasonic wave generating unit 6 goes through the entire first end face 52, the holding table 18 is rotated, while the first moving piece 24 is moved in the Y-axis direction, thereby applying the ultrasonic wave to the entire separation layer 74. Accordingly, the ultrasonic wave is transmitted to the ingot 50 through the layer of water LW to break down the separation layer 74, so that a wafer 76 to be produced can be separated from the ingot 50 with the separation layer 74 as a starting point for separation.

In the ultrasonic wave generating step, a frequency of the ultrasonic wave generated by the ultrasonic wave generating unit 6 is preferably one close to a natural frequency of the ingot 50. By setting the frequency of the ultrasonic wave in this manner, even with the ultrasonic wave having a relatively low output power (substantially 200 W, for example), it is possible to efficiently separate the wafer 76 from the ingot 50 at a relatively short period of time (substantially one to three minutes). The frequency close to the natural frequency of the ingot 50 is, in particular, substantially 0.8 to 1.2 times the natural frequency of the ingot 50, and in a case where the natural frequency of the ingot 50 is 25 kHz, the frequency close thereto is 20 to 30 kHz. Note that, even in a case where the frequency of the ultrasonic wave generated by the ultrasonic wave generating unit 6 is a frequency exceeding the frequency close to the natural frequency of the ingot 50 (the frequency exceeding 30 kHz in the above example), it is possible to efficiently separate the wafer 76 from the ingot 50 at a relatively short period of time as long as the ultrasonic wave has a relatively high output power (substantially 400 to 500 W, for example).

Further, in the ultrasonic wave generating step, a temperature of water supplied between the first end face 52 of the ingot 50 and the end face 6a of the ultrasonic wave generating unit 6 is preferably set to a temperature at which occurrence of cavitation in the layer of water LW is suppressed when the ultrasonic wave is generated by the ultrasonic wave generating unit 6. More specifically, it is preferred to set the temperature of water at 0 to 25° C., and accordingly, an energy of the ultrasonic wave is effectively transmitted to the separation layer 74 without conversion of the energy of the ultrasonic wave into cavitation.

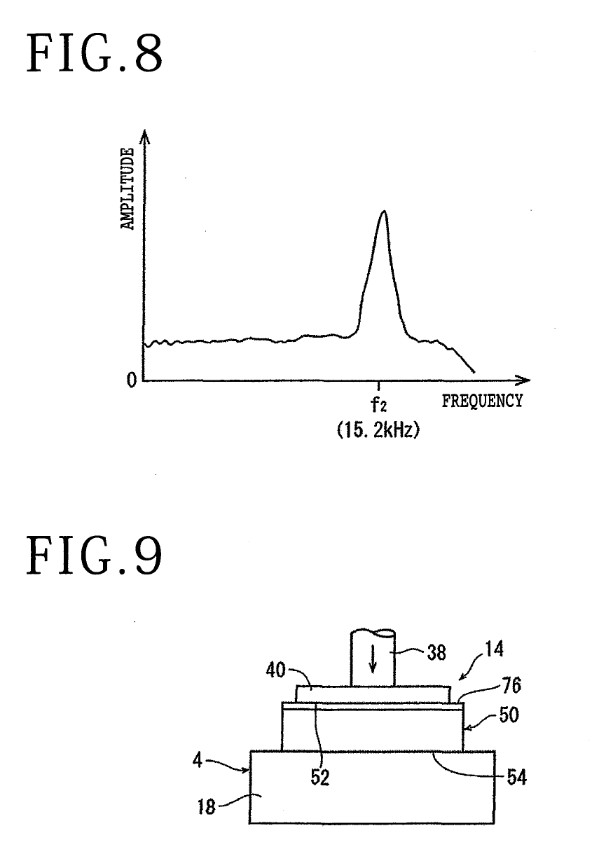

While the ultrasonic wave generating step is being performed as described above, the separation detecting step is performed in which separation of the wafer 76 to be produced from the ingot 50 is detected according to change of sound which is propagated in the air from the ingot 50, and at a time at which it is detected in the separation detecting step that the wafer 76 has been separated from the ingot 50 (at a time at which separation of the wafer 76 has been completed), the ultrasonic wave generating step is ended. In the separation detecting step, sound is collected by the microphone 10, and when a frequency of the collected sound an amplitude of which becomes a peak reaches a predetermined value, it is possible to detect that the wafer 76 has been separated from the ingot 50. When the microphone 10 collects sound in performing the ultrasonic wave generating step, sound having different frequencies is collected. Among these different frequencies, there is a frequency f1 of the sound an amplitude of which becomes a peak. In other words, a relation between a frequency and an amplitude of the sound collected by the microphone 10 before the separation of the wafer becomes a relation indicated in FIG. 7. For example, in a case where both the natural frequency of the ingot 50 and the frequency of the ultrasonic wave are 25 kHz, the frequency f1 of the sound which is collected by the microphone 10 before the separation of the wafer and the amplitude of which becomes a peak is 11.5 kHz. However, when the separation layer 74 is broken down by the ultrasonic wave and the wafer 76 is separated from the ingot 50, as illustrated in FIG. 8, the frequency of the sound which is collected by the microphone 10 and the amplitude of which becomes a peak changes from the frequency f1 into a frequency f2 of 15.2 kHz. Accordingly, in performing the ultrasonic wave generating step, when sound is collected by the microphone 10 and the frequency of the collected sound an amplitude of which becomes a peak reaches a predetermined value, it is possible to detect that the wafer 76 has been separated from the ingot 50.

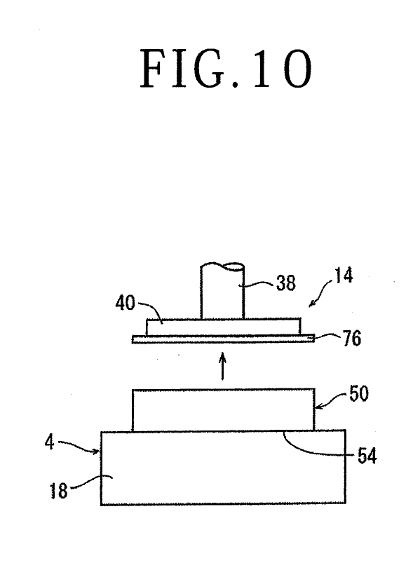

After performing the ultrasonic wave generating step and the separation detecting step, by causing the first motor 26 to move the first moving piece 24, the ultrasonic wave generating unit 6 and the nozzle 36 are moved apart from an upper side of the ingot 50, while at the same time, by causing the second motor 30 to move the second moving piece 28, the wafer holding unit 14 is positioned directly above the ingot 50. Then, as illustrated in FIG. 9, the second elevating means 38 lowers the holding piece 40, thereby bringing the lower surface of the holding piece 40 into contact with the first end face 52. Then, the suction means connected to the holding piece 40 is operated to generate a suction force on the lower surface of the holding piece 40, thereby sucking and holding the separated wafer 76 with the holding piece 40. Then, as illustrated in FIG. 10, the second elevating means 38 moves the holding piece 40 upward, and the second motor 30 is caused to move the second moving piece 28, thereby carrying the separated wafer 76.

As described above, in the present embodiment, it is possible to easily separate the wafer 76 from the ingot 50 with the separation layer 74 as a starting point for separation and to easily determine that the separation of the wafer 76 from the ingot 50 has been completed. In the present embodiment, when the separation of the wafer 76 has been completed, the ultrasonic wave generating step is ended as well. Accordingly, a time taken for the ultrasonic wave generating step need not be unnecessarily increased, thereby achieving enhancement of productivity. In addition, in the present embodiment, water is supplied between a wafer to be produced and the end face 6a of the ultrasonic wave generating unit 6 by the water supplying means 8, whereby the layer of water LW is produced between the wafer to be produced and the end face 6a of the ultrasonic wave generating unit 6. Accordingly, ultrasonic wave is transmitted through the layer of water LW thus generated to the ingot 50, so that the wafer 76 can be separated from the ingot 50 without using a water tank. Hence, it is possible to save time required for accumulating water in the water tank and an amount of water to be used, which is economical.

Note that, in the separation layer forming step in the present embodiment, an example has been described above in which the modified portions 70 are continuously formed in the direction orthogonal to the direction A in which the off angle α is formed and the indexing feeding is carried out in the direction A in which the off angle α is formed; however, the direction in which the modified portions 70 are formed may not be the direction orthogonal to the direction A in which the off angle α is formed, and the direction in which the indexing feeding is carried out may not be the direction A in which the off angle α is formed. In addition, in the present embodiment, an example has been described above in which the first elevating means 32 moving the ultrasonic wave generating unit 6 up and down and the nozzle elevating mechanism moving the nozzle 36 up and down are separately configured; however, it may be configured such that a common elevating mechanism provided in the first moving piece 24 moves the ultrasonic wave generating unit 6 and the nozzle 36 up and down. As an alternative example, it may be configured such that the ultrasonic wave generating unit 6, the nozzle 36, and the wafer holding unit 14 are moved by moving the frame 22 of the Y-axis direction moving mechanism 20 up and down.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A wafer producing method of producing a wafer from a hexagonal single crystal ingot, the method comprising:
a separation layer forming step of positioning a focal point of a laser beam of such a wavelength as to be transmitted through the hexagonal single crystal ingot at a depth corresponding to a thickness of a wafer to be produced from an end face of the hexagonal single crystal ingot and applying the laser beam to the hexagonal single crystal ingot to form a separation layer;
an ultrasonic wave generating step of positioning an ultrasonic wave generating unit so as to face the wafer to be produced with a layer of water interposed therebetween and generating an ultrasonic wave through the layer of water to break down the separation layer; and
a separation detecting step of detecting separation of the wafer to be produced from the hexagonal single crystal ingot according to change in sound.

2. The wafer producing method according to claim 1, wherein
in the separation detecting step, a microphone collects sound, and when a frequency of the collected sound an amplitude of which becomes a peak reaches a predetermined value, it is detected that the wafer has been separated.

3. The wafer producing method according to claim 2, wherein
the hexagonal single crystal ingot is a hexagonal single crystal SiC ingot having a c-axis and a c-plane which is orthogonal to the c-axis, and
in the separation layer forming step, a focal point of a laser beam of such a wavelength as to be transmitted through the hexagonal single crystal SiC ingot is positioned at a depth corresponding to a thickness of a wafer to be produced from an end face of the hexagonal single crystal SiC ingot, and the laser beam is applied to the hexagonal single crystal SiC ingot to form a separation layer including a modified portion in which SiC is separated into Si and C, and cracks isotropically extending along the c-plane from the modified portion.

4. The wafer producing method according to claim 3, wherein
the hexagonal single crystal ingot is a hexagonal single crystal SiC ingot in which the c-axis is inclined with respect to a normal line to an end face thereof and an off angle is formed by the c-plane and the end face, and
in the separation layer forming step, the separation layer is formed by continuously forming the modified portion in a direction orthogonal to a direction in which the off angle is formed to form the cracks isotropically extending along the c-plane from the modified portion, relatively carrying out indexing feeding of the hexagonal single crystal SiC ingot and the focal point within a range not exceeding a width of each of the cracks in the direction in which the off angle is formed, and continuously forming modified portions in the direction orthogonal to the direction in which the off angle is formed to sequentially generate the cracks isotropically extending along the c-plane from each of the modified portions.

5. A wafer producing apparatus which produces a wafer from a hexagonal single crystal ingot in which a separation layer is formed by positioning a focal point of a laser beam of such a wavelength as to be transmitted through the hexagonal single crystal ingot at a depth corresponding to a thickness of a wafer to be produced from an end face of the hexagonal single crystal ingot and applying the laser beam to the hexagonal single crystal ingot, the wafer producing apparatus comprising:
an ultrasonic wave generating unit having an end face which faces the wafer to be produced and generating an ultrasonic wave;
a microphone disposed adjacent to the hexagonal single crystal ingot and collecting sound which is propagated in the air from the hexagonal single crystal ingot; and
separation detecting means coupled with the microphone and detecting separation of the wafer to be produced from the hexagonal single crystal ingot according to change of the collected sound.
